(19) United States
(12) Patent Application Publication
(10) Pub. No.: US 2024/0120240 A1
(43) Pub. Date: Apr. 11, 2024

(54) SETUP METHOD FOR ADJUSTING THE TEMPERATURE CONDITIONS OF AN EPITAXY PROCESS

(71) Applicant: Soitec, Bernin (FR)

(72) Inventor: YoungPil Kim, Grenoble (FR)

(21) Appl. No.: 18/546,210

(22) PCT Filed: Jan. 28, 2022
(86) PCT No.: PCT/EP2022/052002

§ 371 Date: Aug. 11, 2023

(30) Foreign Application Priority Data
Feb. 12, 2021 (FR) 2101375

(51) Int. Cl. H01L 21/66; H01L 21/02

(52) U.S. Cl. CPC H01L 22/26; H01L 21/02381; H01L 21/02532; H01L 22/12; H01L 21/0262

(57) ABSTRACT

A setup method for an epitaxy process intended to form a useful layer on a receiving substrate, comprising:
a) selecting a test substrate:
   having a thickness less than a usual thickness for a given substrate diameter, and/or
   having a low interstitial oxygen concentration, and/or
   comprising a SOI stack;
b) fixing initial temperature conditions defining temperatures to be applied to areas of the substrate;
c) forming a useful layer on the test substrate by applying the epitaxy process with the initial temperature conditions; then, measuring slip line defects;
d) fixing new temperature conditions;
e) forming a useful layer on a new test substrate of the same type, by applying the epitaxy process with the new temperature conditions; then, measuring slip line defects; and
f) comparing the quantity of slip line defects measured on the test structures and choosing the temperature conditions generating the fewest slip line defects.

### CROSS REFERENCE TO RELATED APPLICATIONS

This application is a national phase entry under 35 U.S.C. § 371 of International Patent Application PCT/EP2022/052002, filed Jan. 28, 2022, designating the United States of America and published as International Patent Publication WO 2022/171458 A1 on Aug. 18, 2022, which claims the benefit under Article 8 of the Patent Cooperation Treaty to French Patent Application Serial No. FR2101375, filed Feb. 12, 2021.

### TECHNICAL FIELD

The present disclosure relates to a setup method for adjusting the temperature conditions to obtain minimum thermal stress, prior to the treatment of receiving substrates. This preliminary setup secures the quality of the substrate at the end of the epitaxy process and guarantees optimal use of the associated epitaxy equipment.

### BACKGROUND

Epitaxy methods to grow layers including silicon are commonly used in the field of semiconductor materials and microelectronics. The associated equipment usually implements epitaxy chambers in which the atmosphere (nature of gases and pressure) and temperature are controlled, and in which the substrate to be treated is held by a support.

With the increase in the diameter of the treated substrates (200 mm, 300 mm, even 450 mm), which is accompanied by a densification of the components per substrate, the defects generated during the manufacturing steps (and thus notably epitaxy) must be carefully controlled and limited as much as possible. Defects such as slip lines are particularly critical as they can affect a large area of the substrate; they are typically defects generated during high temperature heat treatments, to which epitaxial growth belongs.

It is usual to determine a process window (in particular related to temperature conditions) for a given epitaxy process, which typically consists of the formation of a useful layer on a receiving substrate: the characteristics of the receiving substrate to be treated and the useful layer to be formed (composition, thickness, crystal structure and quality) are defined to obtain a given structure at the end of the epitaxy process. Treating a receiving substrate in the process window allows one to obtain a final structure that is compliant, in terms of dimensional characteristics of the useful layer as well as in terms of overall quality (defect quantity not exceeding the specified limits), as illustrated in FIG. 1.

Generally, this process window is checked periodically, by processing test substrates between batches of several receiving substrates.

Sometimes the definition of the process window is not precise enough to allow for uniform behavior of all receiving substrates; indeed, since the physical characteristics of the receiving substrates can vary within the same batch or between successive batches, it is not uncommon to observe quality fluctuations between the final structures, even when the epitaxy method has been applied in a similar way, within the process window. In particular, quality fluctuations may result in the uncontrolled appearance of slip lines on some structures. In addition to the loss of yield, such fluctuations generate interruptions in the use of the epitaxy equipment to make new adjustments and thus reduce the uptime of the epitaxy equipment.

### BRIEF SUMMARY

The present disclosure proposes a solution to remedy the above-mentioned problem. It relates to a setup method for an epitaxy process intended to form a useful layer on a receiving substrate in an epitaxy equipment; the setup method is performed before treating the receiving substrate, in order to adjust temperature conditions of the epitaxy process to minimize thermal stress on the substrate to be treated. The setup method ensures a high reproducibility of the receiving substrates characteristics after the epitaxy process is applied, especially with respect to the absence (or very low occurrence) of slip line defects on the final structures.

The present disclosure proposes a setup method for an epitaxy process intended to form a useful layer on a receiving substrate in an epitaxy equipment, the layer and the substrate comprising silicon. The setup method is performed before treating the receiving substrate, and comprises:
a) selecting a type of test substrate among silicon-based wafers:
   having a thickness between 20% and 40% less than a usual thickness for a given substrate diameter, 725 microns and 775 microns being respectively the usual thicknesses for diameters of 200 mm and 300 mm, and/or
   having an interstitial oxygen concentration of less than 10 ppma ASTM '79, and/or
   comprising a SOI stack including a dielectric layer and a thin film of monocrystalline silicon with a thickness less than or equal to 300 nm;
b) fixing initial temperature conditions, the conditions defining temperatures to be applied to at least two areas of the substrate to be processed in the epitaxy equipment;
c) forming the useful layer on a test substrate of the selected type, by applying the epitaxy process with the initial temperature conditions, leading to obtaining an initial test structure; then, measuring slip line defects on the initial test structure;
d) fixing new temperature conditions by varying the temperatures to be applied to the at least two areas of the substrate, compared to the initial temperature conditions;
e) forming the useful layer on a new test substrate of the selected type, by applying the epitaxy process with the new temperature conditions, leading to obtaining a new test structure; then, measuring slip line defects on the new test structure;
f) comparing the quantity of slip line defects measured on the test structures and choosing the temperature conditions of the epitaxy process generating the fewest slip line defects.

According to other advantageous and non-limiting characteristics of the present disclosure, taken individually or in any technically feasible combination:
the steps d) and e) are repeated, once or more times, for other new temperature conditions, before step f);
the epitaxy equipment comprises a plurality of epitaxy chambers, and
   steps b) and d) are performed in parallel, not sequentially, each of those steps applying to a different epitaxy chamber, and then
   steps c) and e) are performed in parallel, the initial and new test substrates being disposed in the different chambers;
the steps d) and e) are repeated, once or more times, for other new temperature conditions, after step f); then step f) is repeated;
steps d) and e) are repeated between 2 and 5 times;
the slip line defects measurement is performed with an optical tool for surface scanning;
the quantity of slip line defects is targeted to correspond to a slip line cumulated length of less than 20 mm, preferentially less than 5 mm;
the temperature conditions define temperatures to be applied to a central area and to a peripheral area of the substrate to be processed in the epitaxy equipment;
the temperature conditions define temperature offset(s) to be applied between a central area and three peripheral areas of the substrate to be processed in the epitaxy equipment;
the variation of the temperatures to be applied to the at least two areas of the substrate, between initial temperature conditions and new temperature conditions, ranges from −30° C. to +30° C.;
the epitaxy process involves temperatures between 600° C. and 1200° C., in an atmosphere comprising at least one gas selected from TCS, DCS, SiH₄, SiCl₄, Si₂H₄, Si₃H₈, GeH₄, and at a pressure between ultra-high vacuum and atmospheric pressure;
the useful layer formed during the epitaxy process is made of silicon and has a thickness of between 0.3 micron and 30 microns;
the useful layer formed during the epitaxy process is made of silicon germanium and has a thickness between 50 nm and 1000 nm.

The present disclosure also concerns an epitaxy method implementing an epitaxy process intended to form a useful layer on a receiving substrate in an epitaxy equipment, the layer and the substrate comprising silicon; the setup method as previously stated is performed before treating the receiving substrate and the receiving substrate is an SOI substrate.

### BRIEF DESCRIPTION OF THE DRAWINGS

Other characteristics and advantages of the present disclosure will appear from the detailed description of embodiments of the present disclosure below, which refers to the attached figures, among which:

FIG. 1 shows a typical process window for an epitaxy process, wherein, for instance, the temperature conditions are adjusted as a function of the resulting defectivity on test wafers;

FIG. 2 represents a map showing the defectivity level (slip line defects) of a structure obtained from step c) of the setup method according to the present disclosure;

FIG. 3 represents a map showing the defectivity level of a structure obtained after step e) of the setup method according to the present disclosure;

FIG. 4 represents a comparison of a conventional process window and the narrow process window defined by using the setup method according to the present disclosure;

FIG. 5 represents an example of implementation of the setup method according to the present disclosure; and

FIG. 6 represents another example of implementation of the setup method according to the present disclosure.

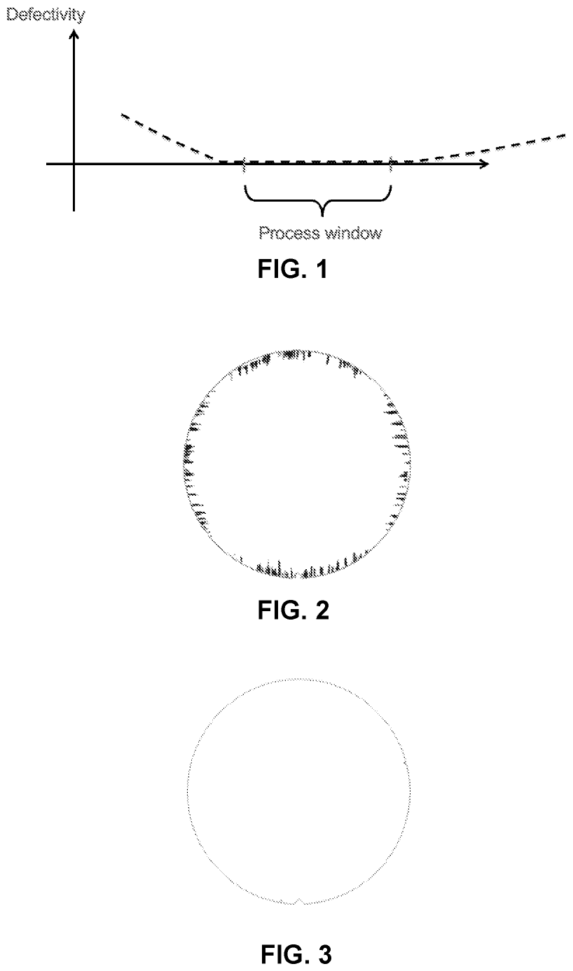

### DETAILED DESCRIPTION

The present disclosure relates to a setup method for an epitaxy process intended to form a useful layer on a receiving substrate in an epitaxy equipment, the layer and the substrate comprising silicon.

The receiving substrate is made of monocrystalline silicon or is mostly formed of monocrystalline silicon; in particular, the receiving substrate can be a Silicon on Insulator substrate (SOI) whose silicon top layer has a thickness ranging from 0.1 to 2.0 microns, whose buried silicon oxide has a thickness ranging from 0.05 to 5.0 microns, and whose base wafer is formed of silicon.

The receiving substrate can be in the form of a circular wafer, with a standard size, for example, 200 mm or 300 mm, or even 450 mm in diameter, as is usually the case in the field of microelectronics. The substrates have a usual thickness for a given diameter: typically, 725 microns, 775 microns and 925 microns are the usual thicknesses for 200 mm, 300 mm and 450 mm diameters, respectively.

The useful layer, formed by epitaxial growth on top of the receiving substrate, can be made of polycrystalline or monocrystalline silicon, with a thickness ranging from 0.3 micron to 30 microns. The useful layer may be p-type or n-type doped, from 1E13/cm³ to around 1E19/cm³.

The useful layer can alternatively be made of silicon germanium, with a thickness ranging from 50 nm to 1000 nm.

The epitaxy process, to which the setup method of the present disclosure applies, is based on a chemical vapor deposition technique (CVD). It typically involves temperatures ranging from 600° C. (SiGe) or 900° C. (Si) to around 1200° C., which temperatures belong to the high temperature range. Depending on the nature of the targeted useful layer, the atmosphere may comprise at least one gas selected from TCS (trichlorosilane), DCS (dichlorosilane), SiH₄ (silane), SiCl₄ (silicon tetrachloride), Si₂H₄ (disilene), Si₃H₈ (trisilane), GeH₄ (germane), and the pressure during epitaxy process may be chosen between ultra-high vacuum and atmospheric pressure.

The setup method is carried out prior to the treatment of the receiving substrate, in order to define a precise and favorable process window, that is to say one that minimizes the thermal stresses seen by the substrate during epitaxial growth in the associated epitaxy equipment. It is known that slip line defects are induced by the thermal stresses applied to a substrate during high temperature heat treatment. The favorable process window is specifically defined to avoid or highly limit the occurrence of such defects.

The setup method first includes a step a) of selecting a type of test substrate based on silicon, with physical and structural characteristics that make the test substrate very sensitive to the formation of slip line defects.

A first type of test substrate corresponds to silicon-based wafers having a thickness between 20% and 40% less than the usual thickness of a wafer of the same diameter. As an example, for a test substrate with a diameter of 200 mm, its thickness will be chosen between 450 and 550 microns; for a test substrate with a diameter of 300 mm, its thickness will be chosen between 500 and 600 microns. The test substrate may be undoped or heavily doped, with type P or N dopants. Heavily doped means a dopant concentration higher than 1×10¹⁸/cm³.

The thickness range chosen for the test substrate according to the first type was identified by the applicant as particularly suitable for refining the process window of the epitaxy process. Indeed, a smaller thickness of the treated substrate allows one to increase the occurrence of slip lines because of enhanced sensitivity to thermal stress. The thickness is nevertheless maintained greater than or equal to 60% of the usual thickness to avoid side effects such as breakage due to thermal stress or mechanical handling issues.

According to a second type, the test substrate is a silicon-based wafer having an interstitial oxygen concentration lower than 10 ppma ASTM '79 (i.e., 5E17 Oi/cm³).

The low interstitial oxygen content in the test substrate promotes the formation of slip lines during high temperature processing due to a reduction in the dislocation locking that results from oxygen precipitates in the silicon.

A third type of test substrate corresponds to a silicon-based wafer comprising, on its front side, a SOI stack including a buried dielectric layer and a thin top layer of monocrystalline silicon with a thickness less than or equal to 300 nm. The dielectric layer, typically made of silicon oxide, can have a thickness between 0.5 and 5.0 microns.

The presence of a SOI stack on the silicon wafer can add a level of mechanical stress to the test substrate and make the test substrate more sensitive to the occurrence of slip line defects. The thin top layer of the SOI stack can also be more slip-line sensitive by thermal stress.

Other types of test substrates can be selected at step a) of the setup method, according to which the test substrates present any combination of the characteristics of the first, second and third types. The most precise process window may be defined from a test substrate with a thin thickness (1st type), with a low interstitial oxygen content (2nd type) and comprising on its front face a SOI stack with a thin layer having a thickness less than or equal to 300 nm (3rd type).

It is to be noted that the characteristics of the test substrates are not linked to the characteristics of the receiving substrate to be processed. The type of test substrate is only chosen for its sensitivity to thermal stresses and will help to define as precisely as possible the temperature conditions for the epitaxy process generating the lowest stress on the receiving substrates, whatever the nature of those receiving substrates may be. According to a preferred embodiment, the test substrate(s) implemented in the setup method are different and totally independent from the receiving substrate(s) to which the epitaxy process is to be applied.

The setup method then comprises a step b) of fixing initial temperature conditions Ti, the conditions defining temperatures to be applied to at least two areas of the substrate to be processed in the epitaxy equipment, during the epitaxy process.

Depending on the equipment, the heating means and their repartition around the substrate to be processed can be different. The heating means are usually based on a lamp system configured to heat inner (center) and outer (peripheral) areas of the processed substrate, such as, for instance, in a Centura® tool from the Applied Materials company. The lamp system can alternatively be configured to offset separately the temperature of three edge areas (named front, side and rear) of the processed substrate, compared to a center area temperature, as in an Epsilon® tool from the ASM company.

The initial temperature conditions Ti may be chosen in an available process window or according to a process condition already used for previously processed receiving substrate, or according to the last optimized process condition. Note that, although the last optimized process was previously tuned, the lowest stress process condition could be varied by tool drift over the time or by periodic maintenance.

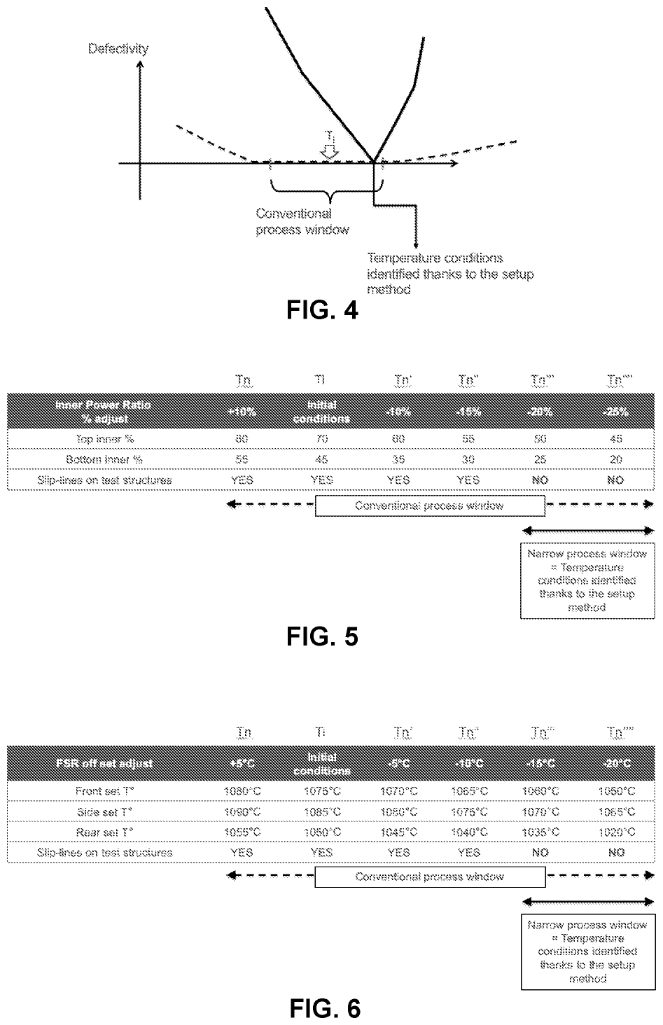

Referring to FIG. 4, the initial temperature conditions Ti can be chosen, for instance, at the center of the conventional process window. Note that the conventional process window is habitually defined by using standard wafers with usual thickness and physical properties, or directly by using receiving substrates. This second option is costly and of course strongly dependent on the characteristics of the receiving substrate.

The setup method then comprises a step c) including the formation of the useful layer on a test substrate of the selected type, by applying the epitaxy process with the initial temperature conditions Ti. This leads to obtaining an initial test structure comprising the test substrate and the useful layer epitaxially grown on top of it.

The step c) then comprises measuring the slip line defects on the initial test structure.

The measurement of slip line defects is carried out by using an optical tool for surface scanning, such as a SP series equipment from KLA company.

FIG. 2 illustrates an example of measurement map, highlighting the slip line defects on the test structure periphery. The quantity of such defects is preferentially evaluated due to a cumulated length of slip lines over the full wafer, eventually considering an edge exclusion ranging from 0.5 to 5 mm. In FIG. 2, the test structure has a 200 mm diameter and the slip line cumulated length is approximately 5×10³ mm.

When a test structure shows a high quantity of slip line defects, like in FIG. 2, after the step c) of the setup method, it is expected that the associated temperature conditions Ti of the epitaxy process won't allow a stable and repeatable behavior of the receiving substrates over the time, even though a portion of the final structures (receiving substrate with the useful layer grown on top of it) won't show any slip line defects. Because the different types of test substrates are highly sensitive to slip lines defects, the setup method is able to identify temperature conditions, within a conventional process window, that may induce a thermal stress on the processed substrate that is too high; the level of thermal stress is susceptible to damage at least part of the receiving substrate due to physical property variations within a batch of receiving substrates or between different batches of receiving substrates.

The next step d) of the setup method includes fixing new temperature conditions Tn by varying the temperatures to be applied to the at least two areas of the processed substrate, compared to the initial temperature conditions Ti.

The variation of the temperatures to be applied to the at least two areas of the processed substrate, between initial temperature conditions Ti and new temperature conditions Tn, advantageously ranges from −30° C. to +30° C.

This temperature adjustment between different areas of the processed substrate influences the thermal stresses applied to the substrate during epitaxial growth.

The setup method then comprises a step e) of forming the useful layer on a new test substrate of the selected type, by applying the epitaxy process with the new temperature conditions Tn. Step e) leads to obtaining a new test structure including the new test substrate and the useful layer grown on top of the test substrate. The slip line defects are then measured on the structure, with the same tool and the same process as in step c).

A measurement map of the new test structure is illustrated in FIG. 3: it is clearly apparent that the quantity of slip lines has drastically decreased. Preferentially, the targeted slip line cumulated length on the test structure is less than 20 mm, or even less than 5 mm.

The step f) of the setup method includes comparing the quantity of slip lines defects measured on the test structures (initial and new) and choosing the temperature conditions of the epitaxy process generating the fewest slip line defects. The “fewest defects” corresponds ideally to the targeted slip line cumulated length stated above, with the ultimate target being zero defects.

If none of the initial and new test structures shows correct level of defectivity, the setup method may involve repeating steps d) and e), one or more times, for other new temperature conditions Tn′, Tn″, Tn′″, etc., after step f). Then, step f) is of course repeated, to compare the new test structures obtained.

The setup method may also comprise repeating steps d) and e), one or more times, for other new temperature conditions Tn′, Tn″, Tn′″, etc., before implementing the step f); the step of comparing the quantity of slip line defects is then applied to the plurality of test structures prepared.

This is typically possible when the epitaxy equipment comprises a plurality of epitaxy chambers in which different temperature conditions, independent of each other, can be defined. Steps b) and d) are thus performed in parallel, not sequentially, each of those steps applying to a different epitaxy chamber. For instance, if five chambers are available, step b) will apply to a first chamber, step d) with first new temperature conditions Tn will apply to a second chamber, step d) with second new temperature conditions Tn′ will apply to a third chamber, etc. A total of five temperature conditions (initial and new) will be thus fixed in the five different chambers.

Then, the steps c) and e) are also performed in parallel, the initial and new test substrates being disposed in the different chambers.

At step f), the initial test structure processed with the initial temperature conditions Ti, and four new test structures processed with distinct temperature conditions Tn, Tn′, Tn″, Tn′″ are available for slip line quantity comparison.

FIG. 4 illustrates the narrow process window identified thanks to the setup method of the present disclosure. The narrow process window corresponds to temperature conditions that lead to no or the fewest slip line defects using one type of the very sensitive test substrates defined in the present disclosure. Those temperature conditions ensure a very high repeatability and stability of the behavior of the receiving substrates when treated according to the epitaxy process.

Before or after step f), the steps d) and e) are advantageously reiterated between two (2) and five (5) times.

The epitaxy process, based on the temperature conditions chosen at step f) can then be implemented on the receiving substrate batches.

### Example 1 of Implementation

The epitaxy equipment is a Centura® tool. The epitaxy process aims to grow a silicon useful layer of 20 microns thick. A bake at 1100° C. for 30 s is applied at the beginning of the process, then the epitaxial growth is performed at 1100° C. for 10 minutes.

The power of the lamps of the heating system can be independently adjusted to define:
the temperature to be applied to the central area of the substrate to be processed, thanks to inner lamps, and
the temperature to be applied to the peripheral area of the substrate, thanks to outer lamps.

The heating system comprises top and bottom lamps, respectively opposite to the front and the back side of the substrate, for each of the central (inner) and peripheral (outer) areas.

The baseline conditions are set here below:
The bottom lamp (inner and outer) power ratio is 60%, meaning that the ratio of the bottom power over the total lamp power is 0.6;
The top inner lamp power ratio is 70%, meaning that the ratio of the top inner lamp power over the total top lamp power is 0.7;
The bottom inner lamp power ratio is 45%, meaning that the ratio of the bottom inner lamp power over the total bottom lamp power is 0.45.

The type of test substrate selected for the setup method corresponds to the first type stated previously. In particular, 200 mm silicon wafers, 500 microns thick and highly boron-doped (20 mohm·cm) are used as test substrates. Note that other types could alternatively have been selected.

The table in FIG. 5 shows the various temperature conditions that were fixed and applied to test substrates in the first example of implementation. The steps d) and e) were performed five times, for five new temperature conditions Tn, Tn′, Tn″, Tn′″, Tn″″. The temperature variation between the different temperature conditions is controlled by increasing or decreasing the percentage ratio of the inner power provided by the top and bottom lamps. In the example, the inner power ratio is varied from +10% to −25%, similarly at the top and the bottom.

This leads to an increase or a decrease in the temperature difference between the inner zone and the outer zone (namely between central and peripheral areas of the processed substrate). The temperature difference, associated to the variation of the inner power ratio, typically ranges from 3° C. to 30° C.

Note that the inner power ratio could be varied in a different way at the top and at the bottom.

After forming the useful layer on the initial test structure and on the five new test structures, with the associated temperature conditions, the step f) reveals the presence of slip lines on the initial test structure and on three other test structures (as stated in the table in FIG. 5). Two test structures, processed with temperature conditions referenced as Tn′″ and Tn″″, do not present any slip lines.

The setup method allows definition of a process window narrower than a conventional process window related to the targeted epitaxy process: the associated temperature conditions ensure a minimum thermal stress on the substrate to be processed. Any receiving substrate can then be processed safely in the narrow process window defined thanks to the setup method according to the present disclosure.

### Example 2 of Implementation

The epitaxy equipment is an Epsilon® tool. The epitaxy process aims to grow a silicon useful layer of 20 microns thick. A bake at 1100° C. for 30 s is applied at the beginning of the process, then the epitaxial growth is performed at 1100° C. for 10 minutes.

The lamps power of the heating system can be adjusted independently to define the temperature offset between the central area of the substrate to be processed and three edge areas, referred to as the front, side and rear, and positioned respectively at the 12 h, 3 h, and 6 h positions on the edge of the wafer.

The baseline conditions are set here below:
The center temperature is set at 1100° C.;
The front offset is −25° C., corresponding a front area temperature of 1075° C.;
The side offset is −15° C., corresponding a side area temperature of 1085° C.;
The rear offset is −50° C., corresponding a rear area temperature of 1050° C.

The type of test substrate selected for the setup method corresponds to the second type stated previously. In particular, 200 mm silicon wafers, 725 microns thick and with low interstitial oxygen content are used as test substrates. Note that other types could alternatively have been selected.

The table in FIG. 6 shows the various temperature conditions that were fixed and applied to test substrates in the second example of implementation. The steps d) and e) were performed five times, for five new temperature conditions Tn, Tn′, etc. The temperature variation between the different temperature conditions is controlled by increasing or decreasing the offset between the central area and the three edge areas.

In the example, the offset is varied from +5° C. to −20° C., similarly for all the three peripheral areas. Note that the offset could be varied in a different way for the three edge areas, thus controlling separately the three edge areas. For instance, the offsets for the front, side and rear areas could be chosen respectively at −10° C., −5° C. and −7° C., in order to fine tune the temperature conditions resulting in the lower thermal stress.

After forming the useful layer on the initial test structure and on the five new test structures, with the associated temperature conditions, the step f) reveals the presence of slip lines on the initial test structure and on three other test structures (as stated in the table in FIG. 6). Two test structures, processed with temperature conditions referenced Tn′″ and Tn″″, do not show any slip lines.

In this second example again, the setup method enables definition of a process window narrower than a conventional process window related to the targeted epitaxy process: the associated temperature conditions ensure a minimum thermal stress on the substrate to be processed. Any receiving substrate can then be processed safely in the narrow process window defined thanks to the setup method of the present disclosure.

Of course, the present disclosure is not limited to the embodiments described and one can add variations of realization without going beyond the scope of the invention as defined by the claims.

1. A setup method for an epitaxy process intended to form a useful layer on a receiving substrate in an epitaxy equipment, the layer and the substrate comprising silicon, the setup method being performed before treating the receiving substrate, and comprising the following steps:
a) selecting a first test substrate comprising silicon, the first test substrate being different from the receiving substrate, the first test substrate:
having a thickness between 20% and 40% less than a thickness for a given substrate diameter, and/or
having an interstitial oxygen concentration of less than 10 ppma, and/or
comprising a SOI stack including a dielectric layer with a thickness in a range extending from 0.5 micron to 5.0 microns, and a thin film of monocrystalline silicon with a thickness less than or equal to 300 nm;
b) fixing initial temperature conditions, the initial temperature conditions defining temperatures to be applied to at least two areas of the first test substrate to be processed in the epitaxy equipment;
c) forming a useful layer on the first test substrate by applying the epitaxy process with the initial temperature conditions to form an initial test structure; then, measuring slip line defects on the initial test structure;
d) fixing new temperature conditions, by varying the temperatures of the initial temperature conditions, to be applied to at least two areas of another test substrate at least substantially the same as the first test substrate;
e) forming a useful layer on the another test substrate, by applying the epitaxy process with the new temperature conditions to form a new test structure; then, measuring slip line defects on the new test structure; and
f) comparing the quantity of slip line defects measured on the initial test structure and the new test structure and choosing the temperature conditions of the epitaxy process generating the fewest slip line defects.

2. The method of claim 1, further comprising repeating the steps d) and e) one or more times, for other new temperature conditions, before step f).

3. The method of claim 1, wherein the epitaxy equipment comprises a plurality of epitaxy chambers, and further comprising:
performing steps b) and d) in parallel, not sequentially, each of the steps b) and d) being performed in a different epitaxy chamber, and then
performing steps c) and e) in parallel, the initial test substrate and the new test substrate being disposed in the different chambers.

4. The method of claim 1, further comprising:
repeating the steps d) and e) one or more times, for other new temperature conditions and other test substrates, after step f); and
then repeating step f).

5. The method of claim 2, wherein the repeating of the steps d) and e) comprising repeating the steps d) and e) between two and five times.

6. The method of claim 1, wherein the measuring of the slip line defects is performed with an optical surface scanning tool.

7. The method of claim 6, wherein the choosing of the temperature conditions of the epitaxy process generating the fewest slip line defects comprises choosing the temperature conditions of an epitaxy process generating slip lines defects corresponding to a slip line cumulated length of less than 20 mm.

8. The method of claim 1, wherein the at least two areas of the first test substrate and the at least two areas of the another test substrate comprise a central area and a peripheral area of the initial test substrate and the another test substrate, respectively.

9. The method of claim 1, wherein the temperature conditions comprise at least one defined temperature offset to be applied between a central area and three peripheral areas of the substrate to be processed in the epitaxy equipment.

10. The method of claim 1, wherein temperature variations between the initial temperature conditions and the new temperature conditions are in a range extending from −30° C. to +30° C.

11. The method of claim 1, wherein the epitaxy process involves temperatures between 600° C. and 1200° C., in an atmosphere comprising at least one gas selected from TCS, DCS, SiH₄, SiCl₄, Si₂H₄, Si₃H₈, GeH₄, and at a pressure between ultra-high vacuum and atmospheric pressure.

12. The method of claim 1, wherein the useful layer formed during the epitaxy process comprises silicon and has a thickness of between 0.3 micron and 30 microns.

13. The method of claim 1, wherein the useful layer formed during the epitaxy process comprises silicon germanium and has a thickness between 50 nm and 1000 nm.

14. An epitaxy method implementing an epitaxy process intended to form a useful layer on a receiving substrate in an epitaxy system, the layer and the substrate comprising silicon, comprising performing the setup method according to claim 1 before epitaxially forming the useful layer on the receiving substrate, wherein the receiving substrate is an SOI substrate.

15. The method of claim 7, wherein choosing the temperature conditions of an epitaxy process generating slip lines defects corresponding to a slip line cumulated length of less than 20 mm comprises choosing the temperature conditions of an epitaxy process generating slip lines defects corresponding to a slip line cumulated length of less than 5 mm.
